(19) United States
(12) Patent Application Publication
(10) Pub. No.: US 2018/0182722 A1
(43) Pub. Date: Jun. 28, 2018

(54) SEMICONDUCTOR MEMORY DEVICE INCLUDING A DUMMY WORD LINE

(71) Applicant: SK hynix Inc., Icheon-si (KR)

(72) Inventors: Young Min KIM, Icheon-si Gyeonggi-do (KR); Sung Ho KIM, Seoul (KR); Sung Soo CHI, Yongin-si Gyeonggi-do (KR); Duk Su CHUN, Icheon-si Gyeonggi-do (KR)

(73) Assignee: SK hynix Inc., Icheon-si (KR)

(21) Appl. No.: 15/681,128

(22) Filed: Aug. 18, 2017

(30) Foreign Application Priority Data
Dec. 27, 2016 (KR) 10-2016-0179758

(51) Int. Cl. H01L 23/60; H01L 27/02; H01L 23/528

(52) U.S. Cl. CPC H01L 23/60; H01L 27/108; H01L 23/5283; H01L 27/0207

(57) ABSTRACT

A semiconductor memory device having dummy word lines is disclosed. In the semiconductor memory device, a number of dummy word lines are arranged at both ends of a cell mat.

### CROSS-REFERENCE TO RELATED APPLICATION

The priority of Korean patent application No. 10-2016-0179758 filed on 27 Dec. 2016, the disclosure of which is hereby incorporated in its entirety by reference, is claimed.

### BACKGROUND

### 1. Technical Field

Embodiments of the present disclosure may generally relate to a semiconductor memory device, and more particularly to a semiconductor memory device relating to the prevention of short-circuiting between a bit line pad and a contact.

### 1. Related Art

Recently, a fabrication process has been developed relating to the fabrication of semiconductor memory devices, such as DRAMs, to implement the increasing integration degrees of the semiconductor memory devices.

However, the distance between a contact and a conductive line is gradually reduced in proportion to the increasing integration degree of the semiconductor memory device, such that there is a higher possibility of short-circuiting between the conductive line and the contact. Specifically, assuming that a pad to be coupled to the contact is formed at the end of the conductive line, the pad is formed to have a larger width than the conductive line, such that the distance from the pad to a contact formed in a different conductive line adjacent to the pad is gradually reduced, resulting in an increased possibility of short-circuiting during the fabrication process of the semiconductor memory device.

Therefore, there is needed a new structure capable of sufficiently increasing the distance between the pad and the contact in such a manner that short-circuiting between the pad and a contact formed in a different conductive line adjacent to the pad can be prevented. More particularly, a semiconductor memory device capable of preventing short-circuiting between the bit line pad and the bit line contact is needed.

### SUMMARY

In accordance with an aspect of the present disclosure, a semiconductor memory device may be provided. The semiconductor memory device may include a cell mat. The semiconductor memory device may include a plurality of dummy word lines disposed arranged at both ends of a cell mat.

### BRIEF DESCRIPTION OF THE DRAWINGS

FIG. 1 is a structural diagram illustrating a semiconductor memory device according to an embodiment of the present disclosure.

FIG. 2A is a structural diagram illustrating an arrangement structure of bit line contacts located at the outermost part of each bit line in both ends of a cell mat when the same number of dummy word lines is formed at both ends of the cell mat.

FIG. 2B is a structural diagram illustrating an arrangement structure of bit line contacts located at the outermost part of each bit line in both ends of a cell mat when different numbers of dummy word lines are formed at both ends of the cell mat.

FIG. 3 illustrates a block diagram of an example of a representation of a system employing a semiconductor memory device with the various embodiments discussed above with relation to FIGS. 1 to 2B.

### DETAILED DESCRIPTION

Reference will now be made in detail to certain embodiments, examples of which are illustrated in the accompanying drawings. Wherever possible, the same reference numbers will be used throughout the drawings to refer to the same or like parts. In the following description, a detailed description of related known configurations or functions incorporated herein will be omitted when it may make the subject matter less clear.

Various embodiments of the present disclosure may be directed to providing a semiconductor memory device including dummy word lines that substantially obviates one or more problems due to limitations and disadvantages of the related art.

An embodiment of the present disclosure may relate to a semiconductor memory device configured to prevent short-circuiting between a bit line pad and a bit line contact during a fabrication process of the semiconductor memory device by improving an arrangement structure of bit line contacts.

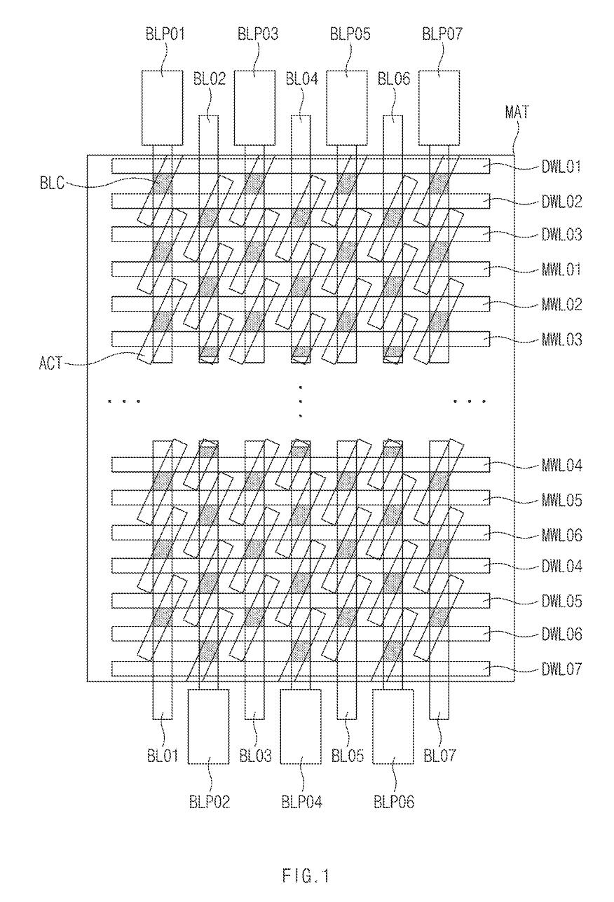

FIG. 1 is a structural diagram illustrating a semiconductor memory device according to an embodiment of the present disclosure.

In an embodiment, for example, the semiconductor device may have a 6F² layout. However, the embodiments are not limited in this way and may have other layouts.

Active regions ACTs, each of which may be defined by a device isolation film and may include a plurality of transistors, may be arranged in a predetermined region of a semiconductor substrate. For example, the active regions ACTs may be arranged in a diagonal direction instead of, for example, a horizontal direction. However, the embodiments are not limited in this way and active regions ACTs may be arranged in different directions then those described.

Main word lines MWL01-MWL06 and dummy word lines DWL01-DWL07 may be formed to extend in a first direction within the active regions ACTs, and bit lines BL01-BL07 extending in a second direction perpendicular to the first direction may be formed over the main word lines MWL01-MWL06 and the dummy word lines DWL01-DWL07.

Bit line pads BLPs coupled to a sense amplifier (sense-amp) may be formed at one end of the bit lines BL01-BL07. For example, the bit line pads BLPs may be alternately arranged at both sides of the cell mat MAT. That is, the bit line pads BLPs of contiguous bit lines may be arranged opposite to each other.

In a region disposed among the main word lines MWL01-MWL06 and dummy word lines DWL01-DWL07 within the active regions ACTs, bit line contacts BLCs formed to couple the active regions ACTs to the bit lines BL01-BL07 may be formed in the region.

The main word lines MWL01-MWL06 and the dummy word lines DWL01-DWL07 may be formed to be buried in the active regions ACTs. The dummy word lines DWL01-DWL07 may be arranged at both sides of the main word lines MWL01-MWL06. That is, the dummy word lines DWL01-DWL07 may be formed at both ends of the cell mat. Different numbers of dummy word lines may be arranged at both ends of the cell mat MAT. For example, a total number of dummy word lines arranged at both ends of the cell mat MAT may be denoted by an odd number. For example, as can be seen from FIG. 1, three dummy word lines DWL01-DWL03 may be arranged at an upper end of the cell mat MAT, and four dummy word lines DWL04-DWL07 may be arranged at a lower end of the cell mat MAT.

The reason why different numbers of dummy word lines DWL01-DWL03 and DWL04-DWL07 are arranged at both ends of the cell mat MAT (i.e., even dummy word lines are arranged at one end of the cell mat MAT and odd dummy word lines are arranged at the other end of the cell mat MAT) is to allow bit line contacts BLCs located at the outermost parts of both ends of the cell mat MAT to have the same arrangement structure. That is, the outermost bit line contacts of the respective bit lines BL01-BL07 in both ends of the cell mat MAT may be arranged to have the same zigzag pattern. As a result, in the contiguous bit lines, defective short-circuiting between the bit line pad BLP and the bit line contact BLC can be prevented.

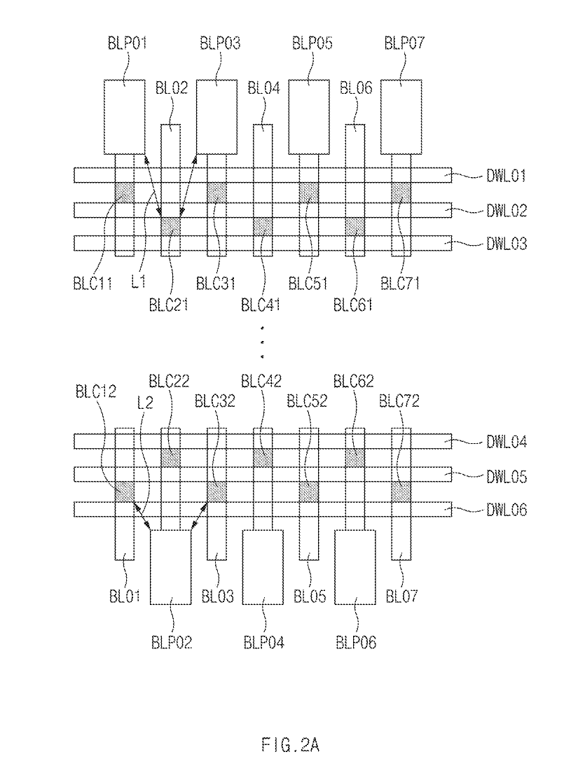

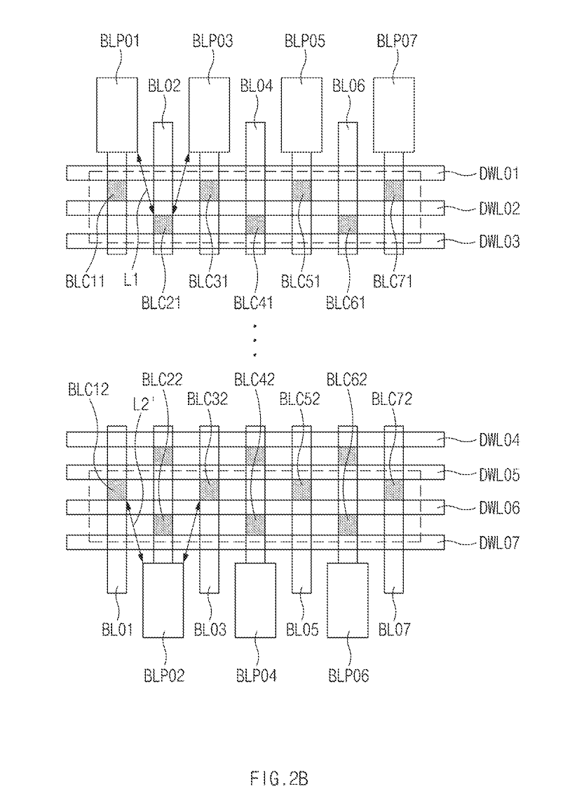

FIG. 2A is a structural diagram illustrating an arrangement structure of bit line contacts located at the outermost part of each bit line in both ends of a cell mat when the same number of dummy word lines is formed at both ends of the cell mat. FIG. 2B is a structural diagram illustrating an arrangement structure of bit line contacts located at the outermost part of each bit line in both ends of a cell mat when different numbers of dummy word lines are formed at both ends of the cell mat.

The arrangement structure of bit line contacts according to an embodiment of the present disclosure will hereinafter be described with reference to the result of a comparison between FIG. 2A and FIG. 2B.

As can be seen from FIG. 2A, the same number (e.g., 3) of dummy word lines DWL01-DWL03 and DWL04-DWL06 may be respectively arranged at both ends of the cell mat. Bit line contacts BLC11-BLC71 and BLC12-BLC72 coupled to the bit lines BL01-BL07 may be disposed between the dummy word lines DWL01-DWL03 and DWL04-DWL06. In this case, in the contiguous bit lines (for example, BL01 and BL02), the distance (i.e., the shortest distance) L1 between the bit line pad BLP01 and the bit line contact BLC21 at the end of one side (i.e., an upper part of FIG. 2A) is sufficiently long, such that there is a low possibility of short-circuiting between the bit line pad BLP01 and the bit line contact BLC21. However, at the end of the other side (i.e., a lower part of FIG. 2A), a distance (i.e., the shortest distance) L2 between the bit line pad BLP02 and the bit line contacts BLC12 and BLC32 is shorter such that there is a higher possibility of short-circuiting between the bit line pad BLP02 and the bit line contacts BLC12 and BLC32, as represented by L2<<L1.

The above-mentioned issues may also occur not only in other bit line pads BLP04 and BLP06, but also in their contiguous bit lines BL03, BL05, and BL07.

However, as illustrated in FIG. 2B, assuming that a dummy word line DWL07 is additionally formed between the dummy word line DWL06 and the bit line pads BLP02, BLP04, and BLP06 such that the bit line contacts BLC11-BLC71 and BLC12-BLC72 formed at both ends of the cell mat may have the same arrangement structure, a distance L2′ between the bit line pad BLP02 and the bit line contacts BLC12 and BLC32 may be elongated by the distance L1 between the bit line pad BLP01 and the bit line contact BLC21, as represented by L2′=L1.

In other words, in association with the same bit lines BL01-BL07 illustrated in FIG. 2A, bit line contacts located at the outermost part of each bit line of the cell mat may be arranged symmetrical to each other on the basis of the center axis (i.e., the center axis having the same progressing direction as in the word line). For example, bit line contacts BLC11-BLC71 formed between the dummy word lines DWL01-DWL03 may be arranged symmetrical to bit line contacts BLC12-BLC72 formed between the dummy word lines DWL04-DWL06 on the basis of the center axis (i.e., the center axis having the same progressing direction as in the word line). That is, in association with the same bit lines BL01-BL07, a zigzag-shaped arrangement structure of the bit line contacts BLC11-BLC71 arranged at the outermost part of each bit line may be symmetrical to a zigzag-shaped arrangement structure of the bit line contacts BLC12-BLC72 arranged at the outermost part of each bit line on the basis of the center axis.

However, in association with the same bit lines BL01-BL07 illustrated in FIG. 2B, bit line contacts located at the outermost parts of each bit line at both ends of the cell mat may have the same arrangement structure. For example, bit line contacts BLC11-BLC71 formed between the dummy word lines DWL01-DWL03 and bit line contacts BLC12-BLC72 formed between the dummy word lines DWL05-DWL07 may have the same arrangement structure. That is, in association with the same bit lines BL01-BL07, a zigzag-shaped arrangement structure of the bit line contacts BLC11-BLC71 arranged at the outermost part of each bit line may be identical to a zigzag-shaped arrangement structure of the bit line contacts BLC12-BLC72 arranged at the outermost part of each bit line.

In the above-mentioned structure in which bit line pads BLPs are alternatively arranged at both ends of the cell mat, bit line contacts located at the outermost parts of both ends of the cell mat may have the same arrangement structure and the distance between the bit line contact and the bit line pad is elongated, such that short-circuiting between each bit line pad and each bit line contact is prevented from occurring in both ends of the cell mat.

As is apparent from the above description, the embodiments of the present disclosure can prevent short-circuiting between a bit line pad and a bit line contact in the semiconductor memory device.

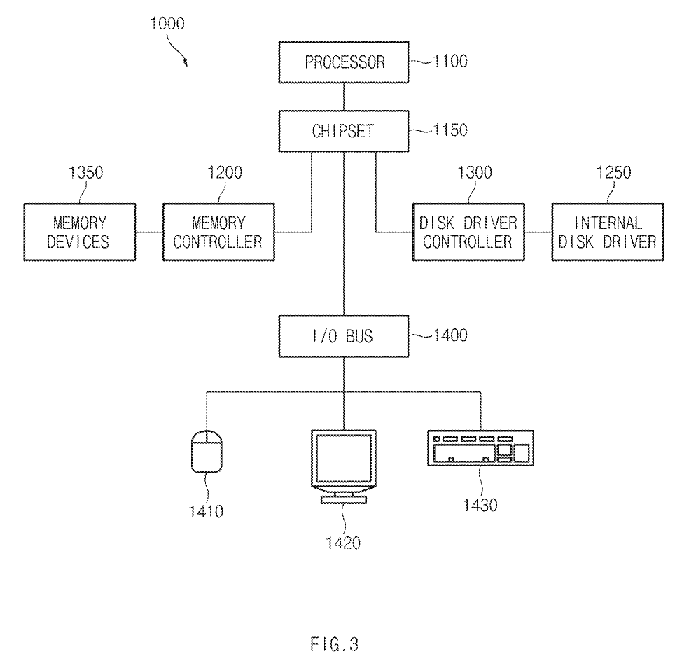

The semiconductor memory devices as discussed above (see FIGS. 1-2B) are particular useful in the design of other memory devices, processors, and computer systems. For example, referring to FIG. 3, a block diagram of a system employing a semiconductor memory device in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1400, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor memory device as discussed above with reference to FIGS. 1-2B. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the semiconductor memory devices as discussed above with relation to FIGS. 1-2B, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1400. The I/O bus 1400 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1400 may employ any one of a number of communications protocols to communicate with the I/O devices 1410, 1420, and 1430. In an embodiment, the I/O bus 1400 may be integrated into the chipset 1150.

The disk driver controller 1300 may be operably coupled to the chipset 1150. The disk driver controller 1300 may serve as the communication pathway between the chipset 1150 and one internal disk driver 1250 or more than one internal disk driver 1250. The internal disk driver 1250 may facilitate disconnection of the external data storage devices by storing both instructions and data. The disk driver controller 1300 and the internal disk driver 1250 may communicate with each other or with the chipset 1150 using virtually any type of communication protocol, including, for example but not limited to, all of those mentioned above with regard to the I/O bus 1400.

It is important to note that the system 1000 described above in relation to FIG. 3 is merely one example of a system including a semiconductor memory device as discussed above with relation to FIGS. 1-2B. In alternate embodiments, such as, for example but not limited to, cellular phones or digital cameras, the components may differ from the embodiments illustrated in FIG. 3.

Those skilled in the art will appreciate that embodiments of the present disclosure may be carried out in other ways than those set forth herein without departing from the spirit and essential characteristics of these embodiments. The above embodiments are therefore to be construed in all aspects as illustrative and not restrictive.

The above embodiments of the present disclosure are illustrative and not limitative. Various alternatives and equivalents are possible. The above embodiments are not limited by the type of deposition, etching polishing, and patterning steps described herein. Nor are the embodiments limited to any specific type of semiconductor device. For example, the present disclosure may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A semiconductor memory device comprising:
a cell mat;
a plurality of first dummy word lines disposed at a first end part of the cell mat; and
a plurality of second dummy word lines disposed at a second end part of the cell mat,
wherein the number of the first dummy word lines is different from the number of the second dummy word lines.

2. The semiconductor memory device according to claim 1, wherein a sum of the number of the first dummy word lines and the number of the second dummy word lines is denoted by an odd number.

3. The semiconductor memory device according to claim 2, wherein:
the first dummy word lines include N dummy word lines (where N is a natural number); and
the second dummy word lines include (N+1) dummy word lines.

4. The semiconductor memory device according to claim 1, further comprising:
bit line contacts located at an outermost part of each bit line in the first end part are substantially identical in arrangement structure to bit line contacts located at an outermost part of each bit line in the second end part.

5. The semiconductor memory device according to claim 4, wherein the arrangement structure is a zigzag-shaped arrangement structure.

6. The semiconductor memory device according to claim 1, further comprising:
a first bit line coupled to a first bit line pad formed at an external part of the first end part; and
a second bit line arranged contiguous to the first bit line, and coupled to a second bit line pad formed at an external part of the second end part,
wherein the shortest distance between a bit line contact arranged at an outermost part and the second bit line pad in the second end part from among bit line contacts coupled to the first bit line is substantially identical to the shortest distance between a bit line contact arranged at an outermost part and the first bit line pad in the first end part from among bit line contacts coupled to the second bit line.

7. A semiconductor memory device comprising:
a cell mat formed to include a plurality of active regions;
a plurality of word lines formed to extend in a first direction substantially perpendicular to the active regions;
a plurality of bit lines formed to extend in a second direction substantially perpendicular to the active regions; and
a plurality of bit line contacts formed to couple the active regions to the bit lines,
wherein an arrangement structure of bit line contacts located at an outermost part of each bit line in a first end part of the cell mat is substantially identical to an arrangement structure of bit line contacts located at an outermost part of each bit line in a second end part of the cell mat.

8. The semiconductor memory device according to claim 7, wherein the plurality of word lines includes a plurality of dummy word lines arranged at both ends of the cell mat.

9. The semiconductor memory device according to claim 8, wherein different numbers of the dummy word lines are arranged at both ends of the cell mat.

10. The semiconductor memory device according to claim 9, wherein a total number of the dummy word lines is denoted by an odd number.

11. The semiconductor memory device according to claim 7, wherein the plurality of bit lines includes:
a first bit line coupled to a first bit line pad formed at an external part of the first end part; and
a second bit line arranged contiguous to the first bit line, and coupled to a second bit line pad formed at an external part of the second end part,
wherein the shortest distance between a bit line contact arranged at an outermost part and the second bit line pad in the second end part from among bit line contacts coupled to the first bit line is substantially identical to the shortest distance between a bit line contact arranged at an outermost part and the first bit line pad in the first end part from among bit line contacts coupled to the second bit line.

12. The semiconductor memory device according to claim 7, wherein the first direction is substantially perpendicular to the second direction.

13. The semiconductor memory device according to claim 7, wherein the arrangement structure is a zigzag-shaped arrangement structure.

14. A semiconductor memory device comprising:
a cell mat;
a plurality of word lines formed to extend in a first direction;
a plurality of bit lines formed to extend in a second direction substantially perpendicular to the first direction; and
a plurality of bit line contacts located between the word lines,
wherein an arrangement structure of bit line contacts located at an outermost part of each bit line in a first end part of the cell mat is substantially identical to an arrangement structure of bit line contacts located at an outermost part of each bit line in a second end part of the cell mat.

15. The semiconductor memory device according to claim 14, wherein the plurality of word lines includes a plurality of dummy word lines arranged at both ends of the cell mat.

16. The semiconductor memory device according to claim 15, wherein different numbers of the dummy word lines are arranged at both ends of the cell mat.

17. The semiconductor memory device according to claim 16, wherein a total number of the dummy word lines is denoted by an odd number.

18. The semiconductor memory device according to claim 14, wherein the plurality of bit lines includes:
a first bit line coupled to a first bit line pad formed at an external part of the first end part; and
a second bit line arranged contiguous to the first bit line, and coupled to a second bit line pad formed at an external part of the second end part,
wherein the shortest distance between a bit line contact arranged at an outermost part and the second bit line pad in the second end part from among bit line contacts coupled to the first bit line is substantially identical to the shortest distance between a bit line contact arranged at an outermost part and the first bit line pad in the first end part from among bit line contacts coupled to the second bit line.
